(19) United States
(12) Patent Application Publication
(10) Pub. No.: US 2013/0106423 A1
(43) Pub. Date: May 2, 2013

(54) MAIN RELAY MONITORING DEVICE AND METHOD FOR GREEN VEHICLE

(71) Applicants: Sanghyeon Moon, Anyang (KR); Youngkook Lee, Seoul (KR); Jin Hwan Jung, Suwon (KR)

(72) Inventors: Sanghyeon Moon, Anyang (KR); Youngkook Lee, Seoul (KR); Jin Hwan Jung, Suwon (KR)

(73) Assignee: HYUNDAI MOTOR COMPANY, Seoul (KR)

(21) Appl. No.: 13/557,547

(22) Filed: Jul. 25, 2012

(30) Foreign Application Priority Data
Oct. 27, 2011 (KR) 10-2011-0110727

(51) Int. Cl. G01R 31/327

(52) U.S. Cl. 324/418

(57) ABSTRACT

Disclosed is a main relay monitoring system and method for a green vehicle, where a main relay is installed between a high voltage battery and an inverter in order to diagnose whether the main relay, which controls the output of the high voltage battery, is fused. In particular a switching operation of an inverter is stopped when an ignition off is detected, and a main relay is turned off and a voltage output of a main battery is cut. Then, a voltage charged at a DC link capacitor is forcibly discharged once the main relay is completely turned off. A voltage of the main battery is then compared to an input voltage of the inverter, and a determination is made based off of this comparison whether the main relay is fused.

### CROSS-REFERENCE TO RELATED APPLICATION

This application claims priority to and the benefit of Korean Patent Application No. 10-2011-0110727 filed in the Korean Intellectual Property Office on Oct. 27, 2011, the entire contents of which are incorporated herein by reference.

### BACKGROUND OF THE INVENTION

(a) Field of the Invention

The present invention relates to a main relay monitoring device and method for a green vehicle, where a main relay is installed between a high voltage battery and an inverter in order to diagnose whether the main relay, which controls the output of the high voltage battery, is fused.

(b) Description of the Related Art

Due to the needs for enhancing the fuel efficiency of vehicles and stricter exhaust gas regulations, green vehicles including hybrid vehicles, fuel cell vehicles, and plug-in electric vehicles are being provided. Green vehicles typically use a power net of high voltage/high current to generate driving torque.

A green vehicle typically uses a motor for generating a required driving torque, an inverter for controlling the driving of the motor, and a power converter (e.g., a DC/DC converter) for converting a high voltage of about 350V to 450V stored in a main battery for supplying power to an electronic unit to a low voltage of 12V required by the electronics unit. A green vehicle uses an inverter to convert a high voltage output from the main battery to a 3-phase alternating current (AC) voltage to then supply the converted voltage to a motor in order to drive the motor. Here, the output of the high voltage stored in the main battery is controlled by a main relay installed between the main battery and the inverter.

For example, the main relay is turned off to cut off output from the main battery when a green vehicle is not being driven, and the main relay is turned on to supply the voltage of the main battery to the inverter when the green vehicle is being driven and requires power from the motor.

When a malfunction of the main battery or the power converter occurs, the main relay cuts off the output voltage of the battery, accordingly. However, when the main relay becomes fused (i.e., stuck together), the main relay cannot cut off the output of the main battery so that the output of high voltage to adjacent circuits continues, thereby increasing the extent of the malfunction and possibly having serious effects on the safety of the vehicle.

Some green vehicles include an additional circuit including a resistor, a transistor, an electric field effect transistor, and a comparator to monitor the state of the main relay. However, when a separate additional circuit is configured as above, power is required to drive the additional circuit, causing unnecessary current consumption, and when the additional circuit malfunctions, there may be a lack of reliability in monitoring the main relay. Further, in this solution, a lot of components are needed to configure the additional circuit, which leads to increased costs and an increase in the size of the entire system.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a main relay monitoring device and method for a green vehicle having the advantages of providing a diagnosis of whether a main relay in a green vehicle is fused by forcibly discharging a voltage charged in a direct current (DC) link capacitor and then comparing a battery voltage with an input voltage of an inverter, when a cut off of a main relay installed between a high voltage battery and an inverter occurs when the ignition of the green vehicle is turned off.

An exemplary embodiment of the present invention provides a main relay monitoring device for a green vehicle, including: a motor; a main battery configured to store a high voltage; a main relay configured to control a voltage output of the main battery; an inverter configured to convert a voltage of the main battery supplied through the main relay to an AC voltage, and supply the AC voltage as a driving voltage to the motor; and a controller configured to cut off the main relay and then forcibly discharging a voltage charged at a DC link capacitor once an ignition is turned off, and compare a voltage of the main battery to an input voltage of the inverter and determine whether the main relay is fused together.

The controller may switch the inverter once the main relay has been completely turned off, and forcibly discharge the voltage charged at the DC link capacitor, through resistance of the motor. After the forcible discharge of the DC link capacitor is completed, the controller may determine that the main relay is fused together when the voltage of the main battery and the input voltage of the inverter are the same or included in a certain range of values, output a malfunction message, and then forcibly turn the power off.

Another embodiment of the present invention provides a main relay monitoring method for a green vehicle, including stopping a switching operation of an inverter when an ignition off is detected, and turning a main relay off and cutting off a voltage output of a main battery; forcibly discharging a voltage charged at a DC link capacitor once the main relay is completely turned off; and comparing a voltage of the main battery to an input voltage of the inverter, and monitoring whether the main relay is fused. The forcible discharging of the DC link capacitor may be performed by using the motor as a resistor.

The main relay may be determined to be fused when the voltage of the main battery and the input voltage of the inverter are the same or within a certain voltage difference range and power may be forcibly turned off. The forcible discharging of the DC link capacitor may be performed by supplying the voltage charged at the DC link capacitor through switching of the inverter to the motor used as a resistor. The main relay may be determined to be normal when a voltage difference between the voltage of the main battery and the input voltage of the inverter voltage exceeds a set reference voltage, and then a normal power down may be performed.

Advantageously, the exemplary embodiment of the present invention reduces costs and simplifies the overall system for monitoring whether a main relay has become fused together. Further, because whether a main relay is fused may be monitored with the ignition off, it is possible to prevent an increase in the extent of malfunctions and provide vehicle safety against exposure to high voltage.

### BRIEF DESCRIPTION OF THE DRAWINGS

FIG. 1 is a drawing schematically illustrating a main relay monitoring device for a green vehicle according to an exemplary embodiment of the present invention.

FIG. 2 is a flowchart schematically illustrating a main relay monitoring process for a green vehicle according to an exemplary embodiment of the present invention.

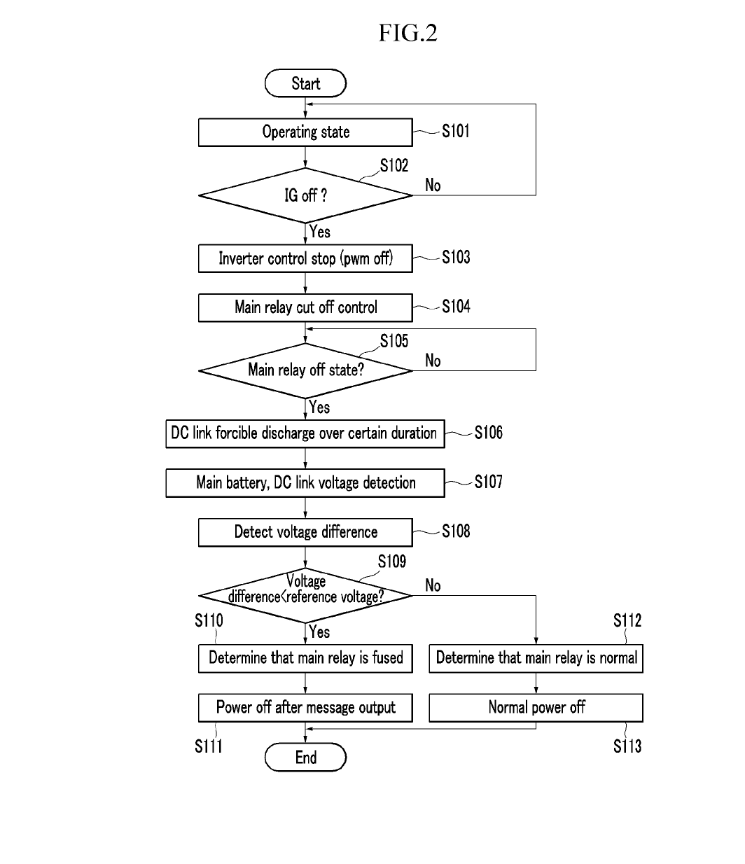

### DESCRIPTION OF SYMBOLS

110: Main battery
120: Main relay
130: Inverter
140: Motor

### DETAILED DESCRIPTION OF THE EMBODIMENTS

The present invention will be described more fully hereinafter with reference to the accompanying drawings, in which exemplary embodiments of the invention are shown.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Furthermore, the control logic of the present invention may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a server or a network. Additionally, although the exemplary embodiment is described as using one control unit to perform the above process, it is understood that the above processes may also be performed by a plurality of control units, controllers, processors or the like.

As those skilled in the art would realize, the described embodiments may be modified in various different ways, all without departing from the spirit or scope of the present invention. The drawings and description are to be regarded as illustrative in nature and not restrictive.

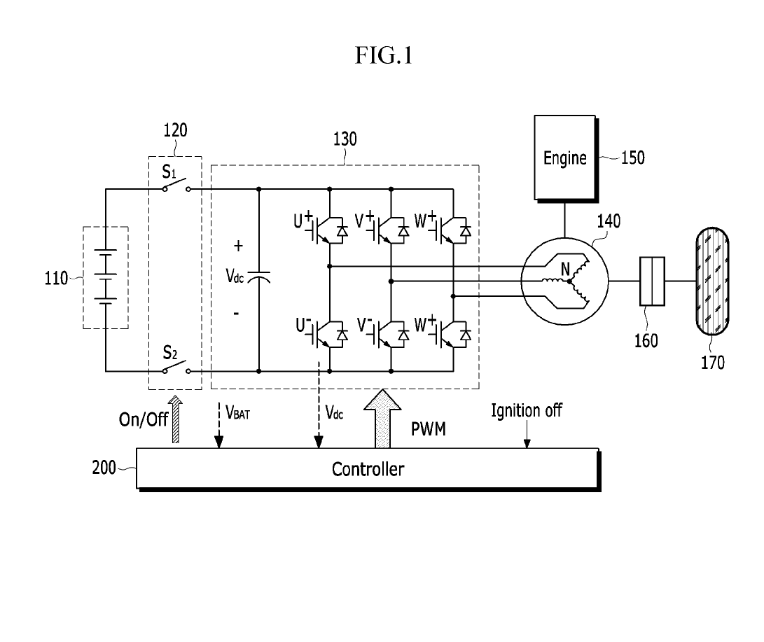

FIG. 1 is a drawing schematically illustrating a main relay monitoring device for a green vehicle according to an exemplary embodiment of the present invention. Referring to FIG. 1, an exemplary embodiment of the present invention includes a main battery 110, a main relay 120, an inverter 130, a motor 140, an engine 150, a transmission 160, drive wheels 170, and a controller 200.

The main battery 110 stores a DC voltage of about 350V to 450V, outputs the stored voltage when required to drive the motor 140, and is charged by voltage generated from the motor 140 while the motor 140 is being operated as a generator during regenerative braking control. The main relay 120 is disposed between the main battery 110 and the inverter 130, is switched through control by the controller 200, and electrically connects or separates the battery 130 and the inverter 130.

The main relay 120 may be switched “off” by the controller 200 when the green vehicle is not being driven and cut off the output of the main battery 110 supplied to the inverter 130, and may be switched “on” by the controller 200 when the green vehicle is driven and power is required to supply the voltage from the main battery 110 to the inverter 130. Further, when a malfunction of the main battery or the power converter occurs, the main relay 120 is switched off by the controller 200 to cut off the output of the main battery 110.

The inverter 130 is configured of power switching devices coupled in series, and includes a pair of U-phase arms U⁺ and U⁻, V-phase arms V⁺ and V⁻, and W-phase arms W⁺ and W⁻. The power switching device may be configured with either an NPN-type transistor, an insulated gate bipolar transistor (IGBT), or a metal-oxide-semiconductor field-effect transistor (MOSFET). The inverter 130 converts a DC voltage of the main battery 110 supplied through the main relay 120 to a 3-phase AC voltage and supplies the AC voltage as a driving voltage to the motor 140, according to a PWM signal applied to each arm by the controller 200.

The motor 140 may be a 3-phase AC motor that generates a driving torque by means of the 3-phase AC voltage supplied from the inverter 130, and operates as a generator during regenerative braking to generate a voltage. The engine 150 is driven at an optimal operating point according to driving conditions. The transmission 160 distributes and transmits power to drive shaft, according to the driving conditions of the vehicle, the output torque of the engine 150 and the motor 140, which is combined and applied through a clutch (not illustrated) according to a driving mode, to the drive wheels 170 at a suitable gear ratio so that the vehicle may be driven. The transmission 160 may be, for example, an automatic transmission or a continuously variable transmission (CVT).

The controller 200 switches the main relay 120 off when an ignition off is detected to cut off the voltage output from the main battery 110, and switches the inverter 130 to forcibly discharge a voltage charged at a DC link capacitor (V_{dc}) by the inverter 130, through the resistance of the motor 140. The forcible discharge of the DC link capacitor (V_{dc}) may be determined, for example, by Equation 1 below.

$$\frac{1}{2} SCS \times {V}^{2} = {I}^{2} SRSt \qquad [ Equation 1 ]$$

Through Equation 1 above, a target discharge duration, a system voltage, and a discharge stop voltage may be determined to determine a discharge current command. For example, when a target discharge duration is 3 seconds and a discharge stop voltage is 60V, the input voltage of the inverter 130 or the output voltage of the DC link capacitor (V_{dc}) is below 60V after 3 seconds.

After forcibly discharging the voltage charged at the DC link capacitor (V_{dc}) of the inverter 130, the controller 200 may compare a voltage (V_{BAT}) of the main battery 110 and the input voltage of the inverter 130 or the output voltage of the DC link capacitor (V_{dc}) and determine whether the main relay 120 is fused.

For example, when the voltage (V_{BAT}) of the main battery 110 and the input voltage of the inverter 130 are the same or included in a certain range of values, the controller 200 may determine that the voltage of the main battery 110 is being continuously supplied to the inverter 130 due to the main relay being fused. When it is determined that the main relay 120 is fused, the controller 200 outputs a malfunction message through a predetermined method and then forcibly turns off the power to the system.

The operation of performing the monitoring of a main relay in a green vehicle including the above described functions according to an exemplary embodiment of the present invention is as follows.

With a green vehicle, to which the present invention is applied, being operated in step S101, the controller 200 determines whether an ignition off is detected in step S102. When the controller 200 determines in step S102 that an ignition off is detected, the output of a pulse-width modulating (PWM) signal applied to arms for each phase U⁺ and U⁻, V⁺ and V⁻, and W⁺ and W⁻ of the inverter 130 is stopped and the switching operation of the inverter 130 is stopped in step S103. Then, the main relay 120 is switched off, and the voltage output of the main battery 110 is cut off in step S104.

Once the switching off control of the main relay 120 is completed in step S105, the controller 200 performs a switching control of the inverter 130 to forcibly discharge a voltage charged at the DC link capacitor (V_{dc}) of the inverter 130 by means of the resistance of the motor 140 in step S106. The forcible discharging of the DC link capacitor (V_{dc}) may determine a target discharge duration, a system voltage, and a discharge stop voltage through Equation 1 above, and a discharge current command may be determined.

In step S106, when the forcible discharge of the voltage charged at the DC link capacitor (V_{dc}) of the inverter 130 is completed, the controller 200 then detects a voltage (V_{BAT}) of the main battery 110 and the input voltage of the inverter 130 or the output voltage of the DC link capacitor (V_{dc}) in step S107. Next, the controller 200 compares the detected voltage (V_{BAT}) of the main battery 110 and the voltage of the inverter 130 and detects the voltage difference in step S108, and determines whether the voltage difference is less than a reference voltage set to determine whether fusing has occurred in S109.

In step S109, when the controller 200 determines that the voltage difference is less than the reference voltage set to determine that fusing has occurred, the controller 200 determines that the main relay 120 is fused in step S110, and outputs a warning message through a set predetermined method and then forcibly turns off the power to the system in step S111.

For example, when the voltage difference between the voltage (V_{BAT}) of the main battery 200 and the input voltage of the inverter 130 is included within a certain range or the voltages are the same, the controller 200 may determine that the voltage of the main battery 110 is continuously being supplied to the inverter 130 due to the main relay being fused. That is, in a state where the main relay 120 is fused, even when the DC link capacitor is forcibly discharged, the voltage of the main battery 110 is continuously supplied, and thus, the voltage (V_{BAT}) of the main battery 110 and the input voltage of the inverter 130 are the same or included in a set reference voltage range.

In step S109, when the voltage difference exceeds the set reference voltage, which is a state in which the output of the main battery 110 is stably cut off by switching off the main relay 120, the controller 200 determines in step S112 that the main relay 120 is not fused and is in a normal state, and performs a normal power off in step S113.

Advantageously, whether a main relay is fused may be conveniently monitored when an ignition off is detected, so that vehicle safety and reliability may be provided using the exemplary embodiment of the present invention.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A main relay monitoring device for a green vehicle, comprising:
a motor;
a main battery storing a high voltage;
a main relay configured to control a voltage output of the main battery;
an inverter configured to convert a voltage of the main battery supplied through the main relay to an alternating current (AC) voltage, and supply the AC voltage as a driving voltage to the motor; and
a controller configured to cut off the main relay and then forcibly discharge a voltage charged at a direct current (DC) link capacitor when an ignition is turned off, compare a voltage of the main battery to an input voltage of the inverter, and determine whether the main relay is fused.

2. The main relay monitoring device for a green vehicle of claim 1, wherein
the controller is configured to switch the inverter once the main relay is completely turned off, and forcibly discharge the voltage charged at the DC link capacitor, through resistance of the motor.

3. The main relay monitoring device for a green vehicle of claim 1, wherein
after the forcible discharge of the DC link capacitor is completed, the controller is configured to determine that the main relay is fused when the voltage of the main battery and the input voltage of the inverter are the same or included within a certain range of values, output a malfunction message, and then forcibly turn off the power.

4. A main relay monitoring method for a green vehicle, comprising:
stopping, by a controller, a switching operation of an inverter when an ignition off is detected, and turning a main relay off and cutting off a voltage output of a main battery;
forcibly discharging, by the controller, a voltage charged at a direct current (DC) link capacitor once the main relay has been completely turned off; and
comparing, by the controller, a voltage of the main battery to an input voltage of the inverter, and monitoring whether the main relay is fused.

5. The main relay monitoring method for a green vehicle of claim 4, wherein
the forcible discharging of the DC link capacitor is performed by using the motor as a resistor.

6. The main relay monitoring method for a green vehicle of claim 4, wherein
the main relay is determined to be fused when the voltage of the main battery and the input voltage of the inverter are the same or within a certain voltage difference range, and power is forcibly turned off.

7. The main relay monitoring method for a green vehicle of claim 5, wherein
the forcible discharging of the DC link capacitor is performed by supplying the voltage charged at the DC link capacitor through switching of the inverter to the motor used as a resistor.

8. The main relay monitoring method for a green vehicle of claim 4, wherein
the main relay is determined to be normal when a voltage difference between the voltage of the main battery and the input voltage of the inverter voltage exceeds a set reference voltage, in response a normal power off is performed.

9. A non-transitory computer readable medium containing program instructions executed by a processor or controller, the computer readable medium comprising:
program instructions that stop a switching operation of an inverter when an ignition off is detected, and turn a main relay off and cut off a voltage output of a main battery;
program instructions that forcibly discharge a voltage charged at a direct current (DC) link capacitor once the main relay has been completely turned off; and
program instructions that compare a voltage of the main battery to an input voltage of the inverter, and monitoring whether the main relay is fused.

10. The non-transitory computer readable medium of claim 9, wherein
the program instructions that forcibly discharge the DC link capacitor are performed using the motor as a resistor.

11. The non-transitory computer readable medium of claim 9, wherein
the main relay is determined to be fused when the voltage of the main battery and the input voltage of the inverter are the same or within a certain voltage difference range, and power is forcibly turned off.

12. The non-transitory computer readable medium of claim 11, wherein
the program instructions that forcibly discharge the DC link capacitor are performed by supplying the voltage charged at the DC link capacitor through switching of the inverter to the motor used as a resistor.

13. The non-transitory computer readable medium of claim 9, wherein
the main relay is determined to be normal when a voltage difference between the voltage of the main battery and the input voltage of the inverter voltage exceeds a set reference voltage, in response a normal power off is performed.
